(19) United States
(12) Patent Application Publication
(10) Pub. No.: US 2020/0162076 A1
(43) Pub. Date: May 21, 2020

(54) COMMUNICATION TRANSMITTER INTERFACE FOR CURRENT-LOOP CIRCUIT

(71) Applicant: Analog Devices Global Unlimited Company, Hamilton (BM)

(72) Inventors: Alan Patrick Cahill, Edinburgh (GB); Michal Brychta, Limerick (IE); Patrick C. Kirby, Limerick (IE)

(21) Appl. No.: 16/193,649

(22) Filed: Nov. 16, 2018

(51) Int. Cl. H03K 19/0175; H03C 3/02; H03D 7/00; H04B 1/04; H04B 1/16; H04L 27/12

(52) U.S. Cl. CPC H03K 19/017509; H03C 3/02; H04L 27/12; H04B 1/04; H04B 1/16; H03D 7/00

(57) ABSTRACT

Techniques for mixing, or modulating, a high-frequency, digital communication signal with a low-frequency, analog current loop signal are provided. In certain examples, the techniques allow mixing the signals in a non-AC coupled manner. In certain examples, such mixing techniques can allow for simplified connections between a modem chip and an analog current loop interface chip of an analog I/O module.

### TECHNICAL FIELD OF THE DISCLOSURE

The present disclosure relates to combined signals, and more particularly, to techniques for transmitting a digital communication signal that is combined with a current loop signal.

### BACKGROUND

Distributed process control systems, like those used in chemical, petroleum, industrial or other process plants to manufacture, refine, transform, generate, or produce physical materials or products typically include one or more process controllers communicatively coupled to one or more field devices via analog, digital or combined analog/digital buses, or via a wireless communication link or network. The field devices, which may be, for example, valves, valve positioners, switches and transmitters (e.g., temperature, pressure, level and flow rate sensors), are located within the process environment and generally perform physical or process control functions such as opening or closing valves, measuring process and/or environmental parameters such as temperature or pressure, etc. to control one or more processes executing within the process plant or system. Smart field devices, such as the field devices conforming to the well-known Fieldbus protocol may also perform control calculations, alarming functions, and other control functions commonly implemented within the controller. The process controllers, which are also typically located within the plant environment, receive signals indicative of process measurements made by the field devices and/or other information pertaining to the field devices and execute a controller application that runs, for example, different control modules which make process control decisions, generate control signals based on the received information and coordinate with the control modules or blocks being performed in the field devices, such as HART®, WirelessHART®, and FOUNDATION® Fieldbus field devices. The control modules in the controller send the control signals over the communication lines or links to the field devices to thereby control the operation of at least a portion of the process plant or system, e.g., to control at least a portion of one or more industrial processes running or executing within the plant or system. In some applications, an analog, or low frequency, current loop control medium, such as wired conductors, can be used to simultaneously communicate analog, low frequency, process information and digital, high-frequency process information. There are opportunities for tighter integration of a high-frequency digital transmitter with the integrated circuit of the current loop interface.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates generally an example of a current-loop system according to various examples of the present subject matter.

FIG. 2 illustrates generally an example mixer circuit for a current loop interface circuit or module according to the present subject matter.

FIG. 3 illustrates generally an example mixer circuit for a current loop interface circuit or module according to the present subject matter.

FIG. 4 illustrates generally an example mixer circuit for a current loop interface circuit or module according to the present subject matter.

FIG. 5 illustrates generally an example mixer circuit for a current loop interface circuit or module according to the present subject matter.

FIG. 6 illustrates generally an example mixer circuit for a current loop interface circuit or module according to the present subject matter.

FIG. 7 illustrates generally a flowchart of an example method of mixing a high-frequency digital communication signal with a DC or very low frequency analog current loop signal.

### DETAILED DESCRIPTION

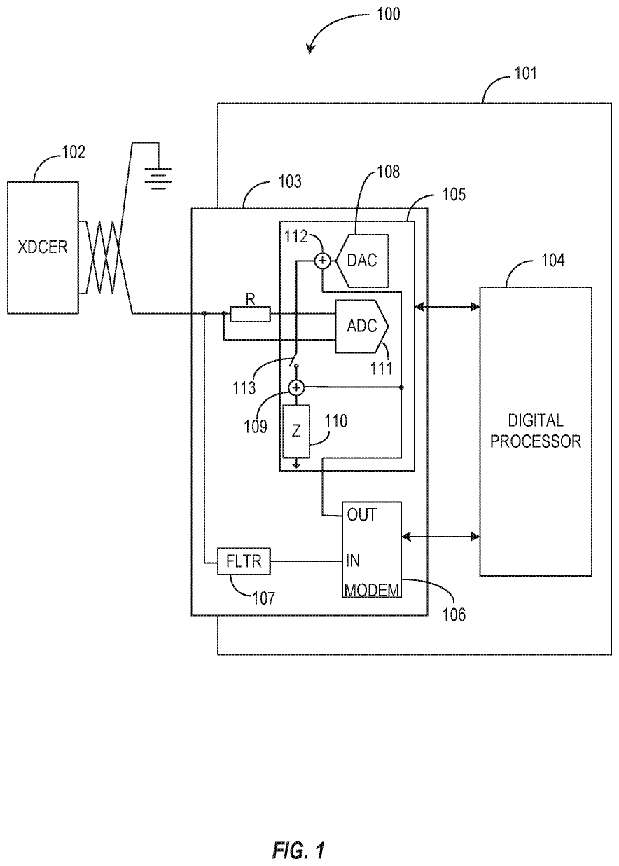

FIG. 1 illustrates generally an example of a current-loop system 100 according to various examples of the present subject matter. The current-loop system 100 can include a controller circuit 101 and one or more field devices 102. The control circuit 101 can come in various forms. An example form can include one or more input/output (I/O) modules 103 and a digital processor 104. In certain examples, the field device 102 can be a sensor transducer. In some examples, the filed device 102 can be an actuator transducer. In some examples, the field device 102 can include a sensor transducer and an actuator transducer. Sensor transducers can control a level of current of the current-loop based on a sensed condition. Actuator transducers can operate an actuator device based on a level of current received via the current-loop. Industrial control applications often use current-loops to communicate analog or discrete information between the field and a process controller. Such industrial systems typically allow the current to vary between 4 milliamps (mA) and 20 mA, however, other ranges of current are possible without departing from the scope of the present subject matter.

In certain applications, the controller circuit 101 can receive information from one or more sources, such as a current-loop sensor, and can control various actuators or indicators, including, for example, a current-loop actuator. In some applications, the controller circuit 101 can be a programmable logic controller (PLC). PLCs can include a main processor 104 that interfaces with multiple forms of input and output (I/O) modules or interfaces, such as digital input modules, digital output modules, analog input modules, analog output modules, heater modules, burner control modules, servo control modules, etc. In certain examples, an I/O module 103 can include an analog current loop interface 105. The analog current-loop interface 105 can be one form of such modules and can provide a bridge between digital controller data of the controller 104 and analog current-loop levels of the current-loop transducer 102. In certain examples, the analog control loop interface circuit 105 can include multiple current-loop channels. In some examples, each channel can be programmable to operate as an analog current input, an analog current output, a discrete input, or a discrete output. In certain examples, a single integrated circuit can include the analog current-loop interface 105. In certain examples, the analog current loop interface 105 can include one or more converters 108, 111 to convert between the analog and digital control environments of the a current-loop system 100. For analog input channels, a series connected resistor (R) can convert the analog current signal to a voltage and the voltage can be received by an analog-to-digital converter (ADC) to provide a digital representation of low frequency analog current signal to the digital processor (DP) 104.

In certain examples, a I/O module 103 including the analog current-loop interface 105 can also include a modem 106 for high-speed communication using the current-loop medium. In certain examples, the modem 106 can include a transmitter, a receiver, a transmitter and a receiver, or a transceiver. In certain examples, a single integrated circuit can include the modem 106. In some examples, the modem 106 is specifically designed to provide digital-over-analog communication. In certain examples, the modem 106 is a frequency shift key (FSK) type modem. In certain examples, the modem 106 employs a highway addressable remote transducer (HART) protocol that can communicate with one or more external devices such as smart transducers via a point-to-point mode or via a multi-drop mode. In certain examples, the analog current loop interface 105 can include one or more mixers 109, 112 to assist in mixing the high-frequency communication signal of a transmitter of the modem 106 with the analog current signal of the analog current loop interface 105. In certain examples employing a modem, the current loop interface 105 can include a switch circuit 113 that can be “open” when the channel of the current loop interface 105 is programmed as an output channel and can be “closed” when the channel of the current loop interface 105 is programmed as an input channel. In certain examples, an impedance 110, having a complex component, can be employed to assist in efficiently receiving a high-frequency communication signal mixed, or modulated, with a low-frequency analog signal on the current loop medium.

The present inventors have recognized opportunities for cleaner integration of a HART-type transmitter with a current-loop interface integrated circuit. More particularly, the present inventors have recognized techniques for the current-loop interface integrated circuit 105 that can allow the HART-type transmitter to mix the high-speed communications with the analog current signal in a non-AC coupled manner. In conventional solutions, the high-frequency modem uses AC-coupling to transmit information onto the analog current loop medium. For example, in existing systems an AC coupling mechanism is used to couple a transmitter of the high-frequency modem with the analog current loop medium. Such coupling can include several components that are external to an integrated circuit for the analog current loop module and an integrated circuit for the high frequency transmitter. In certain examples of the present subject matter, an analog, current-loop I/O module can mix a high-frequency communication signal with the current loop signal in a non-AC-coupled manner, or in a DC-coupled manner. Such direct coupling can eliminate several components associated with conventional systems.

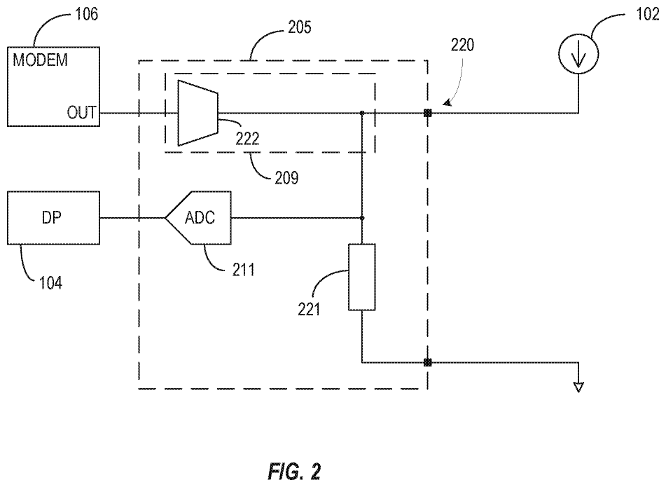

FIG. 2 illustrates generally an example mixer circuit 209 for a current loop interface circuit 205 or module according to the present subject matter. In the illustrated example, the current loop interface circuit 105 is an analog input circuit and can include one or more terminals 220 for receiving the analog signal, a sense resistor 221, and an analog-to-digital converter (ADC) 211, The sense resistor 221 can convert the low-frequency, analog current signal received from for example, an external current loop sensor 102, to a voltage, and the ADC 211 can provide a digital representation of the analog voltage which is an representation of the current level of the current loop. The current loop interface circuit 205 can also include a transconductance amplifier 222. The transconductance amplifier 222 can mix a small, higher frequency signal with the low frequency current signal. In certain examples, a communication transmitter can provide a frequency-shift key (FSK) analog voltage signal to an input of the transconductance amplifier 222. The transconductance amplifier 222 can convert the voltage signal to the small current signal. In certain examples, the transconductance amplifier 222 can source a current equivalent to a gained version of the high-frequency FSK signal into the current loop via the current loop medium. For example, a majority of the sourced current can flow into the relatively lower impedance resistor 221, resulting in a voltage corresponding to the FSK signal on the current loop. The connection of the output of the transconductance amplifier 222 to a terminal 220 or other conductor of the current loop can mix, or modulate, the digital, high frequency communication signal with the current signal of the current loop. The communication signal can be received by any smart device connected to the current loop medium. In certain examples, the sense resistor 221 can be as low as a few ohms, however, it is not unusual to have sense resistors in the range of 100, 150, or 250 ohms, in certain examples. In some examples, the digital, high frequency communication signal received from the transmitter can include a 500 millivolt (mv) peak-to-peak (p-p) signal and the current signal injected by the transconductance amplifier 222 can be about 2.4 mA p-p into a 250 ohm resistor, resulting in a voltage on the loop of about 600 mV peak-to-peak. In certain examples, the digital, high frequency communication signal can shift between multiple frequencies. In some examples, two frequencies of the FSK signal are about 1200 Hz and about 2200 Hz. It is noted that the mixer circuit 209 does not rely on AC-coupling to mix the high-frequency communication signal with the analog, low-frequency, current-loop signal.

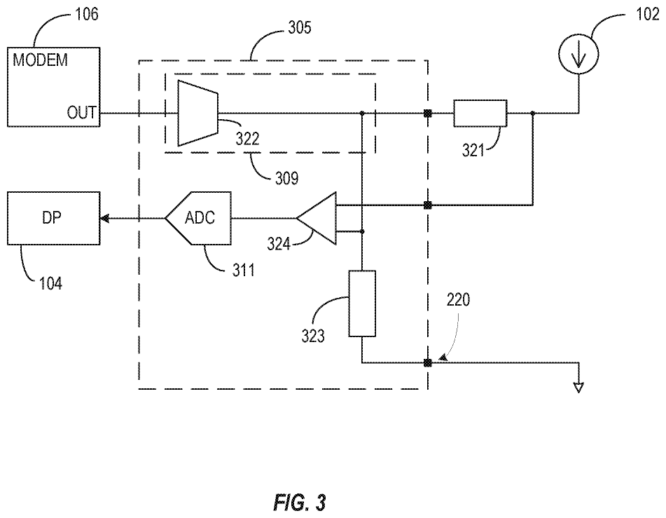

FIG. 3 illustrates generally an example mixer circuit 309 for a current loop interface circuit 305 or module according to the present subject matter. In the illustrated example, the current loop interface circuit 305 is an analog input circuit and can include, an external sense resistor 321, a supplemental resistor 323, an amplifier 324 or buffer, and an analog-to-digital converter (ADC) 311. The sense resistor 321 can convert the low-frequency, analog current signal received from for example, an external current loop sensor 102, to a voltage. The amplifier 324 can receive the differential voltage across the sense resistor 321 and can process the voltage signal for the input of the ADC 311. The ADC 311 can provide a digital representation of the analog voltage which is a representation of the current level of the current loop. The current loop interface circuit 305 can also include a transconductance amplifier 322. The transconductance amplifier 322 can mix a small, higher frequency signal with the low frequency current signal. In certain examples, a communication transmitter can provide a frequency-shift key (FSK) analog voltage signal to an input of the transconductance amplifier 322. The transconductance amplifier 322 can convert the voltage signal to the small current signal. The connection of the output of the transconductance amplifier 322 to a terminal or other conductor of the current loop medium can mix, or modulate, the digital, high frequency communication signal with the current signal of the current loop. The differential sensing of the current signal can eliminate drift or offset anomalies that can be introduced by the transconductance amplifier or other components.

The communication signal can be received by any smart device connected to the current loop. In certain examples, the sense resistor 321 can be as low as a few ohms, however, it is not unusual to have sense resistors in the range of 100, 150, or 250 ohms, in certain examples. In some examples, the digital, high frequency communication signal received from the transmitter can include a 500 millivolt (my) peak-to-peak (p-p) signal and the current signal injected by the transconductance amplifier 322 can be about 2.4 mA p-p into a resistor, such as a 250 ohm resistor, resulting in a voltage on the loop of about 600 mV peak-to-peak. In certain examples, the digital, high frequency communication signal can shift between multiple frequencies. In some examples, two frequencies of the FSK signal are about 1200 Hz and about 2200 Hz. It is noted that the mixer circuit does not rely on AC-coupling to mix the high-frequency communication signal with the analog, low-frequency, current-loop signal. Note that the connection between the integrated circuit of the current loop I/O circuit and the communication modem or transmitter can be a direct connection.

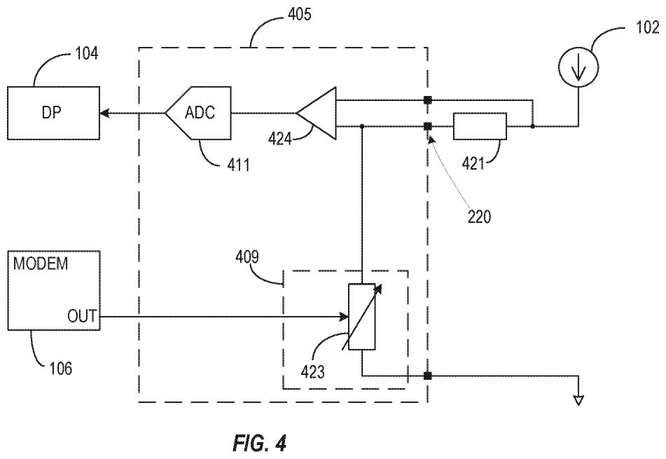

FIG. 4 illustrates generally an example mixer circuit 409 for a current loop interface circuit 405 or module according to the present subject matter. In the illustrated example, the current loop interface circuit 405 is an analog input circuit and can include one or more terminals for receiving the analog signal, an external sense resistor 421, a mixer resistor 409, an amplifier 424 or buffer, and an analog-to-digital converter (ADC) 411. The sense resistor 421 can convert the low-frequency, analog current signal received from for example, an external current loop sensor 102, to a voltage. The amplifier 424 can receive the differential voltage across the sense resistor 421 and can process the voltage signal for the input of the ADC 411. The ADC 411 can provide a digital representation of the analog voltage which is a representation of the current level of the current loop. The differential sensing of the current signal can eliminate drift or offset anomalies that can be introduced by other components coupled to the current loop.

In certain examples, the mixer resistor 409 can provide some current limit capabilities, however, in the present example of FIG. 4, the mixer resistor 409 can be a voltage-controlled resistor. The voltage-controlled resistor can mix, or modulate, a small, higher frequency, voltage signal with the low frequency current loop signal. In certain examples, a communication transmitter can provide a frequency-shift key (FSK) signal to an input of the voltage-controlled resistor. The voltage-controlled resistor 409 can vary the resistance to mix the signal with the current loop signal. The connection of the voltage-controlled resistor 409 in series with the current loop can mix the digital, high frequency communication signal with the current signal of the current loop.

The communication signal can be received by any smart device connected to the current loop. In certain examples, the sense resistor 421 can be as low as 10 ohms, however, it is not unusual to have sense resistors in the range of 100, 150, or 250 ohms, in certain examples. In certain examples, with a given current flowing via the current loop medium, the voltage-controlled resistor can be varied so as to induce an AC voltage on the loop, such as the 600 mV peak-to-peak communication signal discussed above. In certain examples, the digital, high frequency communication signal can shift between multiple frequencies. In some examples, two frequencies of the FSK signal are about 1200 Hz and about 2200 Hz. It is noted that the mixer circuit does not rely on AC-coupling to mix the high-frequency communication signal with the analog, low-frequency, current-loop signal. Note that the connection between the integrated circuit of the current loop I/O circuit and the communication modem 106 or transmitter can be a direct connection.

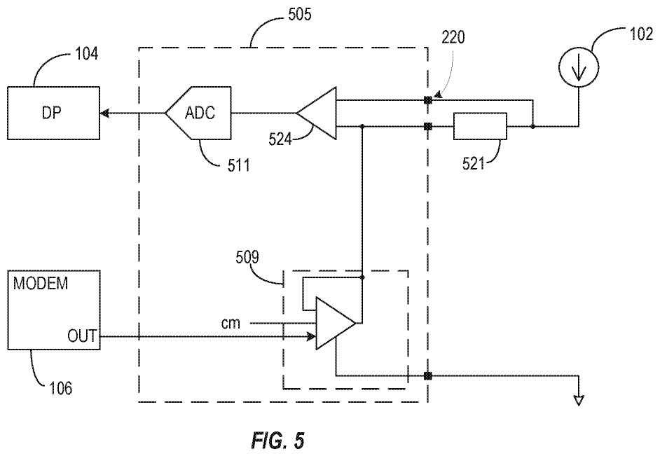

FIG. 5 illustrates generally an example mixer circuit 509 for a current loop interface circuit 505 or module according to the present subject matter. In the illustrated example, the current loop interface circuit 505 is an analog input module and can include one or more terminals for receiving the analog signal, an external sense resistor 521, a mix amplifier 509, a second amplifier 524 or buffer, and an analog-to-digital converter (ADC) 511. The sense resistor 521 can convert the low-frequency, analog current signal received from for example, an external current loop sensor 102, to a voltage. The second amplifier 524 can receive the differential voltage across the sense resistor 521 and can process the voltage signal for the input of the ADC 511. The ADC 511 can provide a digital representation of the analog voltage which is a representation of the current level of the current loop. The differential sensing of the current signal can eliminate drift or offset anomalies that can be introduced by other components coupled to the current loop.

In certain examples, the mix amplifier 509 can mix a small, higher frequency, communication signal with the low frequency current loop signal. In certain examples, a communication transmitter of the modem 106 can provide a frequency-shift key (FSK) signal to an input of the mix amplifier 509. In response to the FSK signal, the mix amplifier 509 can directly modulate a voltage under the sense resistor 521. In some examples, the mix amplifier 509 can receive a common mode signal (CM), either current or voltage, to bias the voltage under the sense resistor 521 at an appropriate level to allow for circuit headroom. The connection of the output of the mix amplifier 509 with the current loop can mix the digital, high frequency communication signal with the current signal of the current loop.

The communication signal can be received by any smart device connected to the current loop. In certain examples, the sense resistor 521 can be as low as 10 ohms, however, it is not unusual to have sense resistors in the range of 100, 150, or 250 ohms, in certain examples. In some examples, the digital, high frequency communication signal received from the transmitter of the modem 106 can be a digital signal or an analog signal. In certain examples, the mix amplifier 509 can modulate a AC voltage onto the loop. In certain examples, the digital, high frequency communication signal can shift between multiple frequencies. In some examples, two frequencies of the FSK signal are about 1200 Hz and about 2200 Hz. It is noted that the mixer circuit 509 does not rely on AC-coupling to mix the high-frequency communication signal with the analog, low-frequency, current-loop signal. Note that the connection between the integrated circuit of the current loop I/O circuit and the communication modem or transmitter can be a direct connection.

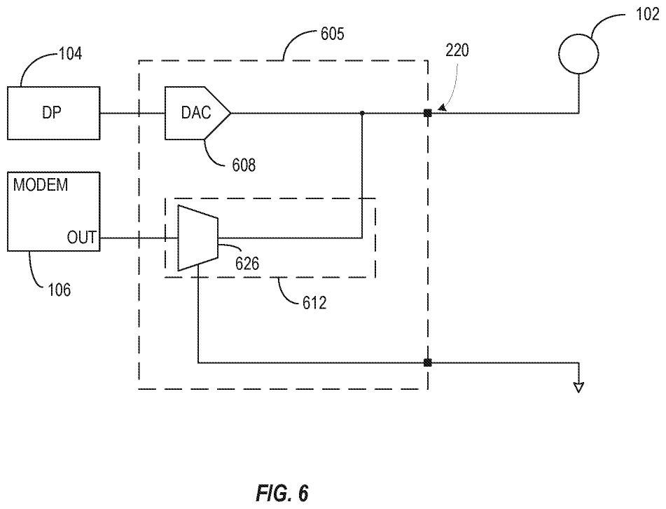

FIG. 6 illustrates generally an example mixer circuit 612 for a current loop interface circuit 605 or module according to the present subject matter. In the illustrated example, the current loop interface circuit 605 is an analog output module and can include one or more terminals for connecting to the current loop and a digital-to-analog converter (DAC) 608. The DAC 608 can receive a digital value and can set the current level of the current loop for reception by a current loop transducer 102. The current loop interface circuit 605 can also include a transconductance amplifier 626 as part of the mixer circuit 612. The transconductance amplifier 626 can mix a small, higher frequency, communication signal with the low frequency current signal. In certain examples, a communication transmitter of a modem 106 can provide a frequency-shift key (FSK) analog voltage signal to an input of the transconductance amplifier 626. The transconductance amplifier 626 can convert the voltage signal to the small current signal. The connection of the output of the transconductance amplifier 626 to a terminal or other conductor of the current loop can mix the digital, high frequency communication signal with the current signal of the current loop.

The communication signal can be received by any smart device connected to the current loop. In some examples, the digital, high frequency communication signal received from the transmitter can include a 500 millivolt (mv) peak-to-peak (p-p) signal and the current signal injected by the transconductance amplifier 626 can be about 1 mA p-p. In certain examples, the digital, high frequency communication signal can shift between multiple frequencies. In some examples, two frequencies of the FSK signal are about 1200 Hz and about 2200 Hz. It is noted that the mixer circuit 612 does not rely on AC-coupling to mix the high-frequency communication signal with the analog, low-frequency, current-loop signal. Note that the connection between the integrated circuit of the current loop I/O circuit and the communication modem or transmitter can be a direct connection.

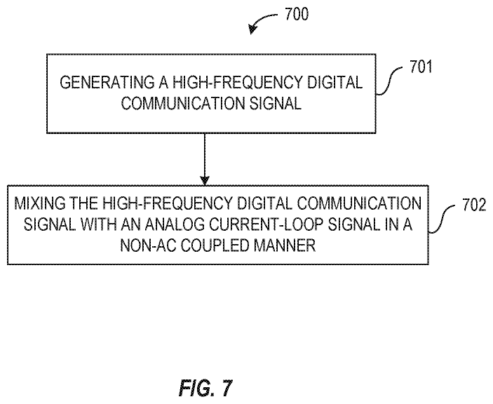

FIG. 7 illustrates generally a flowchart of an example method 700 of mixing a high-frequency digital communication signal with a DC or very low frequency analog current loop signal. At 701, a modem can generate a high-frequency, digital communication signal such as an FSK signal. The modem can be an integrated circuit of an analog I/O current module. The FSK signal can be received at an analog current interface circuit. The analog current interface circuit can be an integrated circuit of the analog I/O current module. At 702, a mixer of the analog current interface circuit can mix the high-speed digital communication voltage signal with the current loop signal being set by, or received by, the analog current interface circuit. The mixer can mix the signal using non-AC coupled techniques. Such techniques can allow for simplified connections between the transmitter of the modem IC and the analog current interface IC.

In certain examples, the mixer can include a transconductance amplifier coupled to a conductor of the current loop signal. In some examples, the mixer can include a controllable device to mix the signal at a node underneath or downstream from a sense resistor of the analog current interface circuit. In certain examples, the mixer can be a controllable resistance. In some examples, the mixer can be a buffer configured to directly modulate a voltage of the current loop underneath a sense resistor. In certain examples, the analog current interface circuit can include one or more of an ADC or DAC to control or sense a level of the current loop. In certain examples, the analog current interface can be programmable to operate in one of a plurality of input or output modes.

### Various Notes & Examples

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of“at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, the terms “including” and “comprising” are open-ended, that is, a system, device, article, composition, formulation, or process that includes elements in addition to those listed after such a term are still deemed to fall within the scope of subject matter discussed. Moreover, such as may appear in a claim, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of a claim. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. The following aspects are hereby incorporated into the Detailed Description as examples or embodiments, with each aspect standing on its own as a separate embodiment, and it is contemplated that such embodiments can be combined with each other in various combinations or permutations.

1. A current loop interface circuit configured to couple to and communicate information with an external device based on a level of current of a first current signal, the current loop interface circuit including an integrated circuit comprising:
a digital-to-analog converter (DAC) configured to modulate the level of current during a first mode of operation of the current loop interface circuit;
an analog-to-digital converter (ADC) configured to provide a digital representation of the level of current during a second mode of operation of the current loop interface circuit;
an FSK input terminal configured to electrically connect to a frequency shift key (FSK) transmitter to receive an FSK signal; and
a mixer circuit, coupled to the FSK input terminal, the mixer circuit configured to mix the FSK signal with the first current signal in a non-ac coupled manner during the second mode of operation.

2. (canceled)

3. The current loop interface circuit of claim 1, including:
a first sense resistor coupled in series between the external device and a reference voltage.

4. The current loop interface circuit of claim 3, including a transconductance amplifier configured to receive the FSK signal and to inject a corresponding FSK current signal at the first node of the first sense resistor.

5. The current loop interface circuit of claim 3, wherein the integrated circuit is configured to couple with a second sense resistor, wherein the second sense resistor is configured to couple in series with the first sense resistor and between the first sense resistor and the external device.

6. The current loop interface circuit of claim 5, wherein the mixer circuit includes the first sense resistor.

7. The current loop interface circuit of claim 6, wherein the ADC is configured to convert a voltage induced by the current signal across the second sense resistor to ameliorate influence of signal offset on the first current signal.

8. The current loop interface circuit of claim 3, wherein the first sense resistor is a voltage-controlled resistor configured to receive the FSK signal, to change a resistance based on the FSK signal, and to mix an FSK voltage with the first current signal.

9. The current loop interface circuit of claim 3, including a mix amplifier configured to sink the first current signal, to receive the FSK signal, and to mix an FSK voltage signal with the first current signal.

10. The current loop interface circuit of claim 9, wherein the mix amplifier is configured to receive a common mode signal to allow for circuit headroom.

11. The current loop interface circuit of claim 1, including a control logic configured to enable an analog-to-digital converter to provide a multiple-bit, digital representation of the level of the current of the first current signal.

12. The current loop interface circuit of claim 1, including control logic configured to receive a bit representative of one of two binary levels of the first current signal and to enable a digital-to-analog converter to modulate the level of the current of the first current signal based on the bit.

13. The current loop interface circuit of claim 1, including control logic configured to receive a multiple-bit, digital representation of a desired current level of the first current signal and to enable a digital-to-analog converter of the current loop interface to modulate the level of the current of the first current signal based on the multiple-bit, digital representation.

14. (canceled)

15. A method of mixing a communication signal with an analog current loop signal at a current loop interface integrated circuit, the method comprising:
setting a current level of the first current signal in a first mode of operation:
providing a digital representation of the current level of the first current signal in a second mode of operation;
generating a frequency shift key signal; and
mixing the FSK signal with an analog current loop signal in a non-AC coupled manner during the second mode of operation.

16. The method of claim 15, wherein the mixing includes:
receiving the FSK signal at a transconductance amplifier of the current loop interface integrated circuit; and
injecting an output of the transconductance amplifier into the analog current loop signal at a first node of a sense resistor of the current loop.

17. The method of claim 15, wherein the mixing includes:
receiving the FSK signal at a voltage-controlled resistor of a current loop interface integrated circuit; and
modulating a resistance of the voltage-controlled resistor, under a sense resistor of the current loop, in response to the FSK signal.

18. The method of claim 15, wherein the mixing includes:
receiving the FSK signal at a buffer of a current loop interface integrated circuit; and
directly modulating a voltage of the current loop, under a sense resistor of the current loop, in response to the FSK signal using an output of the buffer.

19-20. (canceled)

21. A current loop interface circuit configured to couple to and communicate information with an external device based on a level of current of a first current signal, the current loop interface circuit including an integrated circuit comprising:
means for setting a current level of the first current signal in a first mode of operation;
means for providing a digital representation of the current level of the first current signal in a second mode of operation;
means for receiving a frequency shift key (FSK) signal for transmission to the external device; and
means for mixing the FSK signal with the first current signal in a non-ac coupled manner during the second mode of operation.

22. The current loop interface circuit of claim 21, wherein the integrated circuit includes:
an analog-to-digital converter configured to provide a digital representation of the level of current of the first current signal received from the external device in a first mode of operation of the current loop interface circuit; and
a digital to analog converter configured to provide a current level setpoint of the first current signal during a second mode of operation of the current loop interface circuit.

23. The current loop interface circuit of claim 21, wherein the means for mixing include a voltage-controlled resistor configured to receive the FSK signal, to change a resistance based on the FSK signal, and to mix an FSK voltage of the FSK signal with the first current signal.

24. The current loop interface circuit of claim 21, wherein the means for mixing includes an amplifier configured to sink the first current signal, to receive the FSK signal, and to mix an FSK voltage signal of the FSK signal with the first current signal.
